(19) United States
(12) Patent Application Publication
(10) Pub. No.: US 2003/0197222 A1
(43) Pub. Date: Oct. 23, 2003

(54) Method for manufacturing semiconductor device, semiconductor device, electro-optical device, and electronic apparatus

(75) Inventors: Hiroyuki Hara, Chino-shi (JP); Satoshi Inoue, Chino (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/394,059

(22) Filed: Mar. 24, 2003

(30) Foreign Application Priority Data
Mar. 27, 2002 (JP) 2002-089702

(51) Int. Cl. H01L 27/01

(52) U.S. Cl. 257/347

(57) ABSTRACT

The invention provides a method of manufacturing a semiconductor device, capable of enhancing characteristics of each semiconductor element constituting the semiconductor device, while reducing or suppressing non-uniformity in the characteristics thereof. When forming a thin-film circuit constructed by arranging a plurality of pixel circuits on a glass substrate, first, a plurality of concave portions to be seeds in crystallizing a semiconductor film are formed on the glass substrate with a pitch n times an array pitch of a plurality of pixel circuits. Then, an amorphous silicon film is formed on the glass substrate on which the concave portions are formed, and by crystallizing the silicon film by heating, a substantially monocrystalline silicon film is formed within a region centered on the concave portions. Using each of the substantially monocrystalline silicon film formed substantially centered around the respective concave portions, pixel circuits are formed.

### BACKGROUND OF THE INVENTION

1. Field of Invention

The present invention relates to a method for manufacturing a semiconductor device, a semiconductor device, an electro-optical device, and an electronic apparatus.

2. Description of Related Art

In the related art, electro-optical devices, such as liquid-crystal display devices or EL (electroluminescence) display devices, include a thin-film circuit having thin-film transistors as semiconductor elements which allow the switching of pixels to be carried out. In such related art thin-film transistors, the active regions, such as channel regions, are typically formed by amorphous silicon films, and in addition, polycrystalline silicon films are also widely used for this purpose. However, the use of a polycrystalline silicon film allows the electrical characteristics, such as electron mobility, to be enhanced, compared to the amorphous silicon film, consequently enhancing performance of the thin-film transistors.

### SUMMARY OF THE INVENTION

When forming a thin-film circuit to be used in electro-optical devices, it is necessary to form a silicon film on a relatively large substrate (for example, a glass substrate). However, when the silicon film is formed by related art methods, such as a solid-state growth method or an annealing method that utilizes laser irradiation to enhance the crystallinity of the silicon film, a plurality of grain boundaries are formed over the whole silicon film formed on the substrate.

Since these grain boundaries exist in disordered states on the substrate, they are also found in the areas where the thin-film transistors (specifically, the areas where the channel regions are formed) constituting the thin-film circuit are formed. Since a thin-film transistor that is formed in an area having a grain boundary has poor characteristics compared to a thin-film transistor that is formed in an area not having a grain boundary, there is non-uniformity in the characteristics between the thin-film transistor that is formed in the area having a grain boundary and the thin-film transistor that is formed in the area not having a grain boundary. Such non-uniformity in characteristics between such a plurality of thin-film transistors causes deterioration of electro-optical devices using a thin-film circuit having these thin-film transistors.

The present invention provides a method of manufacturing a semiconductor device that is capable of enhancing the characteristics of each semiconductor element constituting the semiconductor device, while reducing or suppressing non-uniformity in the characteristics thereof.

Further, the present invention provides a semiconductor device in which the characteristics of each semiconductor element constituting the semiconductor device can be enhanced while reducing or suppressing the non-uniformity thereof.

Furthermore, the present invention provides an electro-optical device having an excellent display quality.

In order to address or accomplish the above, the present invention provides a method of manufacturing a semiconductor device having a thin-film circuit constructed by arranging a plurality of unit circuits having thin-film elements on an insulating substrate. The method includes forming a plurality of seed portions to be seeds in crystallizing a semiconductor film on the insulating substrate; forming the semiconductor film on the insulating substrate on which the seed portions have been formed; a crystallizing the semiconductor film by carrying out heating; and forming the thin-film circuit in the semiconductor film on which the heating has been carried out. The plurality of seed portions are formed to have a pitch n times an array pitch of the plurality of unit circuits.

Paying attention to the regularity in the array positions of the respective unit circuits formed on the substrate, since the plurality of seed portions are formed to have a pitch n times an array pitch of the plurality of unit circuits and crystal grains are grown by carrying out the crystallization of the semiconductor film, it is possible to form a plurality of crystal grains with an array pitch corresponding to the regularity in the array positions of the unit circuits.

Specifically, when “1” is selected as n, it is possible to form crystal grains with a pitch (that is, a pitch one time the array pitch of the unit circuits) the array pitch of the unit circuits. By doing so, a thin-film circuit can be formed such that one crystal grain includes one unit circuit. Further, when “2” is selected as n, it is possible to form crystal grains with a pitch two times the array pitch of the unit circuits. By doing so, a thin-film circuit can be formed such that one crystal grain includes one to four unit circuits. Furthermore, when “3” or larger number is selected as n, the same results can be obtained.

That is, according to the present invention, a thin-film circuit can be formed such that one crystal grain includes at least one unit circuit as a whole. Therefore, it is possible for the grain boundaries to not be included in the respective unit circuits, and it is also possible to enhance the characteristics of the thin-film elements (for example, semiconductor elements) constituting the respective unit circuits. Further, since the difference in characteristics between the respective thin-film elements caused by the presence or absence of the grain boundaries can be reduced or prevented, it is possible to reduce or suppress the non-uniformity in characteristics between the respective thin-film elements constituting each of the unit circuits.

Furthermore, the present invention provides a method of manufacturing a semiconductor device having a thin-film circuit constructed by arranging a plurality of unit circuits having thin-film elements on an insulating substrate. The method includes: forming a plurality of seed portions to be seeds in crystallizing a semiconductor film on the insulating substrate; forming the semiconductor film on the insulating substrate on which the seed portions have been formed; crystallizing the semiconductor film by carrying out heating; and forming the thin-film circuit in the semiconductor film on which the heating has been carried out. The plurality of seed portions are formed to have a pitch n times an array pitch of the respective thin-film elements included in each of the unit circuits.

Paying attention to the regularity in the array positions of the respective thin-film elements included in each of unit circuits, since a plurality of seed portions are formed to have a pitch n times an array pitch of the plurality of thin-film elements and crystal grains are grown by carrying out the crystallization of the semiconductor film, it is possible to form a plurality of crystal grains with an array pitch corresponding to the regularity in the array positions of the thin-film elements.

Specifically, when “1” is selected as n, it is possible to form crystal grains with a pitch (that is, a pitch one time the array pitch of the thin-film elements) the array pitch of the thin-film elements. By doing so, a thin-film circuit can be formed such that one crystal grain includes one thin-film element. Further, when “2” is selected as n, it is possible to form the crystal grains with a pitch two times the array pitch of the thin-film elements. By doing so, a thin-film circuit can be formed such that one crystal grain includes one to four thin-film elements. Furthermore, when “3” or larger number is selected as n, the same results can be obtained.

That is, according to the present invention, a thin-film circuit can be formed such that one crystal grain includes at least one thin-film element as a whole. Therefore, it is possible for the grain boundaries not to be included in the respective unit circuits, and it is also possible to enhance the characteristics of the thin-film elements constituting the respective unit circuits. Further, since the difference in characteristics between the respective thin-film elements caused by the presence or absence of the grain boundaries can be reduced or prevented, it is possible to reduce or suppress the non-uniformity in characteristics between the respective thin-film elements constituting each of the unit circuits.

Furthermore, when the seed portions are formed with a pitch one times the array pitch of the thin-film elements, and supposing that the array pitch of the plurality of unit circuits is P1 and the number of the thin-film elements included in one unit circuit is m, then, the array pitch in forming the seed portions may be expressed as (1/m)×P1, and the same results can be obtained by forming the seed portions on the basis of such correspondence. Similarly, when the seed portions are formed with a pitch two times the array pitch of the thin-film elements, since the array pitch in forming the seed portions may be expressed as (2/m)×P1, the same results can be obtained by forming the seed portions on the basis of such correspondence. When the seed portions are formed with a pitch three or more times the array pitch of the thin-film elements, the same results can be obtained.

It is preferable that the seed portions are concave portions formed in the insulating substrate. By doing so, it is possible to easily position seeds in crystallization.

Preferably, the heating in the heating step is carried out such that the portions of the semiconductor film in the concave portions are not melted while other portions are melted. As such, the crystallization of the semiconductor film on which the heating has been carried out proceeds toward the periphery from the inner portion, specifically, near to the bottom portion, of the concave portion. At that time, by properly setting the size of the concave portion, only one crystal grain reaches the upper portion (the opening portion) of the concave portion. Thus, in the melted portion of the semiconductor film, since the crystallization proceeds using the one crystal grain having reached the upper portion of the concave portion as a nucleus, it is possible to form the substantially monocrystalline semiconductor film within a region substantially centered around the concave portion. Since a thin-film circuit can be formed by using a substantially monocrystalline semiconductor film, it is possible to markedly enhance the characteristics compared to using the amorphous or polycrystalline semiconductor film.

It is preferable that the heating in the heating step is carried out by laser irradiation. By using the laser, it is possible to carry out the heating more efficiently. Various lasers such as an excimer laser, a solid laser and a gas laser can be considered.

Preferably, the semiconductor film formed in the semiconductor film forming step is an amorphous or polycrystalline silicon film. By crystallizing it, it is possible to form a substantially monocrystalline silicon film within a region substantially centered around the seed portions and to subsequently obtain a thin-film element through a high quality rendered by this silicon film.

It is preferable that the thin-film element includes a thin-film transistor. By doing so, it is possible to form a thin-film transistor having excellent characteristics and small non-uniformity in the characteristics.

Preferably, the unit circuit is an aggregate of thin-film elements performing predetermined functions. The thin-film element can be a thin-film transistor, a thin-film passive element (such as resistor, capacitor etc.), MIM (metal insulator metal) element, TFD (thin-film diode) or the like.

For example, it is preferable that the unit circuit is a pixel circuit of an electro-optical device. By doing so, it is possible to form a pixel circuit having excellent characteristics and small non-uniformity in the characteristics.

Furthermore, it is preferable that the unit circuit is a unit memory circuit of a memory device. By doing so, it is possible to form a unit memory circuit having excellent characteristics and small non-uniformity in the characteristics.

Furthermore, it is preferable that the unit circuit is a unit logic circuit of a field-programmable gate array (FPGA) device. By doing so, it is possible to form a unit logic circuit having excellent characteristics and small non-uniformity in the characteristics.

Furthermore, the present invention provides a semiconductor device including a thin-film circuit constructed by arranging a plurality of unit circuits having thin-film elements on an insulating substrate. The insulating substrate defines step portions formed to have a pitch n times an array pitch of the plurality of unit circuits. Each of the plurality of unit circuits is formed by a substantially monocrystalline semiconductor film by carrying out heating on the semiconductor film formed on the insulating substrate to crystallize the semiconductor film using the step portions as seeds.

Paying attention to the regularity in the array positions of the respective unit circuits on the substrate, since the step portions are formed with a pitch n times the array pitch of the plurality of unit circuits and the crystallization of the semiconductor film proceeds using these step portions as seeds, a substantially monocrystalline semiconductor film is formed with an array pitch corresponding to the regularity in the array positions of the unit circuits. By doing so, a thin-film circuit can be formed such that one monocrystalline semiconductor film includes at least one unit circuit as a whole. Therefore, since the grain boundary is not included in the respective unit circuits, it is possible to enhance the characteristics of the thin-film elements constituting each of the unit circuits. Further, since the difference in characteristics between the respective thin-film elements caused by the presence or absence of the grain boundaries can be reduced or prevented, it is also possible to reduce or suppress non-uniformity in the characteristics of the respective thin-film elements constituting the respective unit circuits.

Furthermore, the present invention provides a semiconductor device including a thin-film circuit constructed by arranging a plurality of unit circuits having thin-film elements on an insulating substrate. The insulating substrate defines step portions formed to have a pitch n times an array pitch of the respective thin-film elements included in the unit circuits. The respective thin-film elements are formed by a substantially monocrystalline semiconductor film by carrying out heating on the semiconductor film formed on the insulating substrate to crystallize the semiconductor film using the step portions as seeds.

Paying attention to the regularity in the array positions of the thin-film elements included in each of the unit circuits, since the step portions are formed with the pitch n times the array pitch of the plurality of thin-film elements and the crystallization of the semiconductor film proceeds using these step portions as seeds, a substantially monocrystalline semiconductor film is formed on the insulating substrate with an array pitch corresponding to the regularity in the array positions of the thin-film elements. By doing so, a thin-film circuit can be formed such that one monocrystalline semiconductor film includes at least one thin film as a whole. Therefore, since the grain boundary is not included in the respective thin-film elements, it is possible to enhance the characteristics of the thin-film elements constituting each of the unit circuits. Further, since the difference in characteristics between the respective thin-film elements caused by the presence or absence of the grain boundaries can be reduced or prevented, it is possible to reduce or suppress non-uniformity in the characteristics of the respective thin-film elements constituting the respective unit circuits.

It is preferable that the step portions as mentioned above are concave portions formed in an insulating film deposited on the insulating substrate. By doing so, it is possible to easily position seeds in crystallization.

Preferably, the semiconductor film formed on the insulating substrate is an amorphous or polycrystalline silicon film. By doing so, it is possible to form the substantially monocrystalline silicon film within a region substantially centered around the seed portions and to subsequently obtain a thin-film element through a high quality rendered by this silicon film.

It is preferable that the thin-film element comprises a thin-film transistor. By doing so, it is possible to obtain a thin-film transistor having excellent characteristics and small non-uniformity in the characteristics.

Preferably, the unit circuit is a pixel circuit of an electro-optical device. By doing so, it is possible to obtain a pixel circuit having excellent characteristics and small non-uniformity in the characteristics and to obtain an electro-optical device of excellent quality by using such pixel circuit.

It is preferable that the unit circuit is a unit memory circuit of a memory device. By doing so, it is possible to obtain a unit memory circuit having excellent characteristics and small non-uniformity in the characteristics and to construct a memory device of excellent quality (for example, RAM) by using such unit memory circuit.

Preferably, the unit circuit is a unit logic circuit of a field-programmable gate array (FPGA) device. By doing so, it is possible to construct a unit logic circuit having excellent characteristics and small non-uniformity in the characteristics, and to obtain an FPGA device of good quality by using such unit logic circuit.

It is preferable that an electro-optical device is constructed to include the above-mentioned pixel circuit. By doing so, it is possible to construct an electro-optical device (such as a liquid-crystal display device, organic electroluminescence display device and the like) having an excellent display quality. Furthermore, it is also possible to construct an electronic apparatus of excellent quality by using such electro-optical device.

### BRIEF DESCRIPTION OF THE DRAWINGS

FIG. 1 is a schematic illustrating a semiconductor device obtained by the manufacturing method according to the present invention;

FIGS. 2(a) and 2(b) are schematics illustrating forming a silicon film on a glass substrate;

FIGS. 3(a)-3(c) are schematics illustrating forming the silicon film on the glass substrate;

FIG. 4 is a plan view illustrating the silicon film formed on the glass substrate;

FIGS. 5(a)-5(d) are schematics illustrating forming a thin-film transistor;

FIGS. 6(a) and 6(b) are schematics illustrating an exemplary embodiment in which grain filters are formed with a pitch two times the array pitch of cells;

FIGS. 7(a) and 7(b) are schematics illustrating an exemplary embodiment in which the grain filters are formed with a pitch one times the array pitch of thin-film transistors;

FIGS. 8(a) and 8(b) are schematics illustrating an exemplary embodiment in which the grain filters are formed with a pitch two times the array pitch of the thin-film transistors;

FIG. 9 is a perspective view illustrating a personal computer using a display device according to the present invention;

FIG. 10 is a perspective view illustrating a portable phone using a display device according to the present invention;

FIG. 11 is a perspective view illustrating a digital still camera using a display device according to the present invention;

FIG. 12 is a perspective view illustrating an electronic book using a display device according to the present invention.

### DETAILED DESCRIPTION OF PREFERRED EMBODIMENTS

Exemplary embodiments of the present invention are described below with reference to the drawings.

[First Exemplary Embodiment]

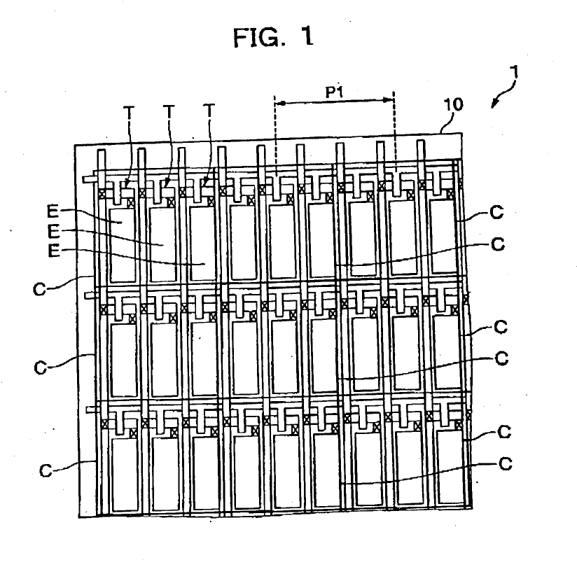

FIG. 1 is a schematic illustrating a semiconductor device obtained by a manufacturing method according to the present invention and which also illustrates a portion of a liquid-crystal display device.

As shown in FIG. 1, a cell (pixel circuit) C, which is a unit circuit functioning as a unit pixel of the liquid-crystal display device, includes three thin-film transistors T and three electrode portions E respectively connected to the three thin-film transistors T to apply an electric field to a liquid-crystal layer (not shown). The three electrode portions E correspond to color pixels of three colors (R, G and B). These cells C are regularly formed on a glass substrate 10 with a predetermined array pitch P1, and a thin-film circuit 1 is formed by providing wiring between the respective cells C using gate wiring lines and source wiring lines.

Next, a method of manufacturing the thin-film circuit 1 is explained in detail below. The manufacturing method according to the present exemplary embodiment includes: (1) forming, on the glass substrate 10, a silicon film for using as an active region of the thin-film transistors T, and (2) forming the thin-film transistors T using the formed silicon film. The respective steps are explained in detail below.

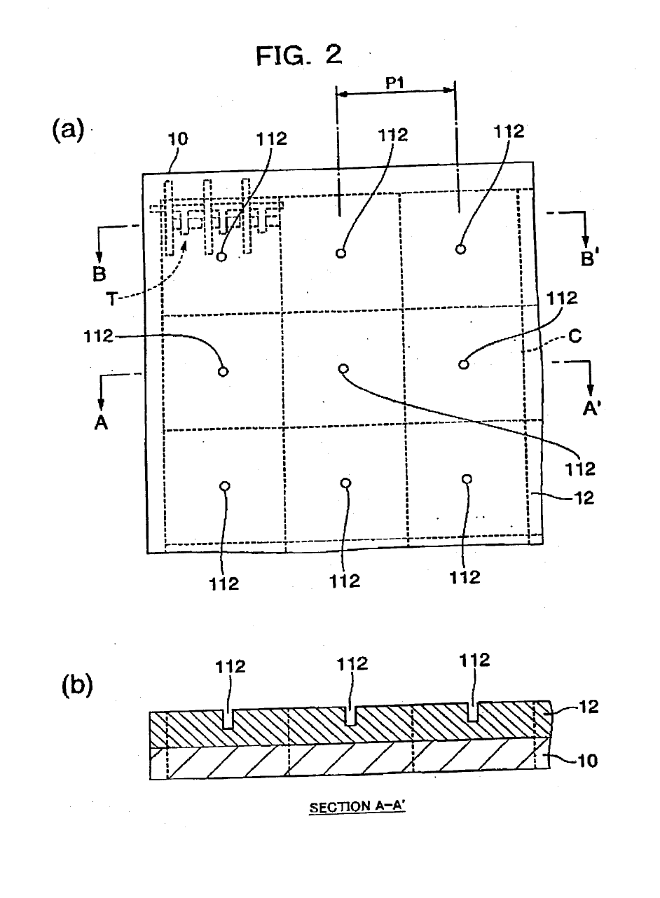

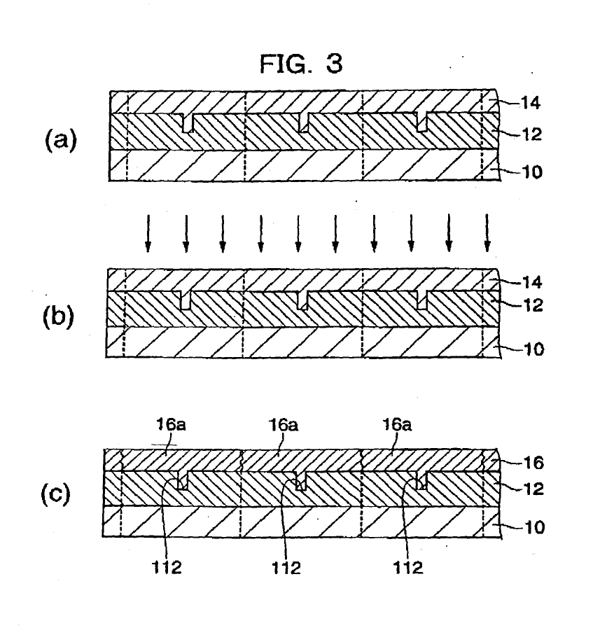

FIGS. 2(a)-3(c) are schematics illustrating an SOI (silicon on insulator) step of forming a silicon film on the glass substrate (insulating substrate) 10. FIG. 2(a) is a partial plan view of the glass substrate 10 on which a silicon film is formed. Further, a sectional view shown in FIG. 2(b) corresponds to a section taken along plane A-A′ shown in FIG. 2(a).

As shown in FIGS. 2(a) and 2(b), a silicon oxide film 12 is formed on the glass substrate 10 as an insulating film. It is preferable that the silicon oxide film 12 is formed by film formation methods such as a plasma enhanced chemical vapor deposition (PECVD) method, a low-pressure chemical vapor deposition (LPCVD) method, and a sputtering method.

Next, concave portions (hereinafter “grain filters”) 112 are formed at predetermined positions of the upper surface of the silicon oxide film 12. A grain filter means a hole to grow only a single crystal nucleus. Specifically, the respective grain filters 112, as shown in FIG. 2(a), are formed such that one grain filter corresponds to one area (an area corresponding to one pixel) indicated by dotted lines on the glass substrate 10, in which one cell C is expected to be formed. As described below, it is possible to form the respective grain filters 112 on the glass substrate 10 to have a proper pitch, which can be obtained by multiplying the array pitch P1 of the cells C by a natural number n (n=1, 2, 3, . . . ) as well as a pitch equal to the array pitch P1.

The above grain filters 112 can be formed, for example, by exposing and developing a photo-resist film applied on a silicon oxide film using the arrangement mask of the grain filters 112 to form the photo-resist film (not shown) having openings to expose formation positions of the grain filters 112 on the silicon oxide film 12, carrying out reactive ion etching using the photo-resist film as an etching mask, and then removing the photo-resist film on the silicon oxide film 12. It is preferable that the grain filters 112 are formed, for example, in a cylindrical shape having a diameter of about 50 to 500 nm and a height of about 750 nm. Further, the grain filters 112 may be formed in any shape other than the cylindrical shape (such as a prism shape). Furthermore, when the grain filters having a smaller diameter are formed, by growing an oxide film in the radial direction from the side wall of the concave portion (hole portion) by the PECVD method and the like, it is possible to reduce the hole diameter.

Next, as shown in FIG. 3(a), an amorphous silicon film 14 is formed on the silicon oxide film 12 and within the grain filters 112 by film formation method, such as the LPCVD method. It is preferable that the amorphous silicon film 14 be formed with a thickness of about 50 to 300 nm. Further, in place of the amorphous silicon film 14, a polycrystalline silicon film may be formed.

Next, as shown in FIG. 3(b), the silicon film 14 is subjected to laser irradiation. It is preferable that the irradiation process, for example, be carried out at an energy density of about 0.4 to 1.5 J/cm² by using an XeCl pulsed excimer laser having a wavelength of about 308 nm and a pulse width of about 20 to 30 ns. By carrying out the laser irradiation under these conditions, most of the irradiated laser light is absorbed near the surface of the silicon film 14. This is because the amorphous silicon has a relatively large absorption coefficient of 0.139 nm⁻¹ at the wavelength (308 nm) of the XeCl pulsed excimer laser.

Further, in the laser irradiation of the glass substrate 10, it is possible to properly select the irradiation method in accordance with the capability (irradiation area) of an apparatus to be used for the irradiation process. For example, when the irradiation area is small, a method of selectively irradiating the respective grain filters 112 and the vicinities thereof can be considered. Further, when the irradiation area is relatively large, a method of sequentially selecting regions including several grain filters 112 and repeating the laser irradiation for the selected regions a certain number of times can be considered. Furthermore, when the apparatus has a high capability, the laser irradiation may be carried out for one region including all the grain filters 112 at the same time.

By properly selecting the conditions of the laser irradiation as mentioned above, the silicon film 14 on the bottom portions in the grain filters 112 remains unmelted while the silicon film 14 at the other portions is substantially melted in its entirety. By doing so, the crystal growth of silicon after the laser irradiation starts near the bottom portions of the grain filters 112 and proceeds toward the surface of the silicon film 14, that is, the substantially melted portions.

Several crystal grains are generated at the bottom portions of the grain filters 112. At that time, by setting the size of the cross-section of the grain filters 112 (diameter of a circle in the present embodiment) equal to or slightly smaller than that of one crystal grain, only one crystal grain reaches the upper portions (opening portions) of the grain filters 112. By doing so, the crystal growth proceeds with one crystal grain having reached the upper portion of the grain filter 112 being a nucleus in the substantially melted portions of the silicon film 14, as shown in FIG. 3(c), so that a silicon film 16 is formed by regularly arranging substantially monocrystalline silicon films 16a composed of crystal grains of large diameter centered around the grain filters 112.

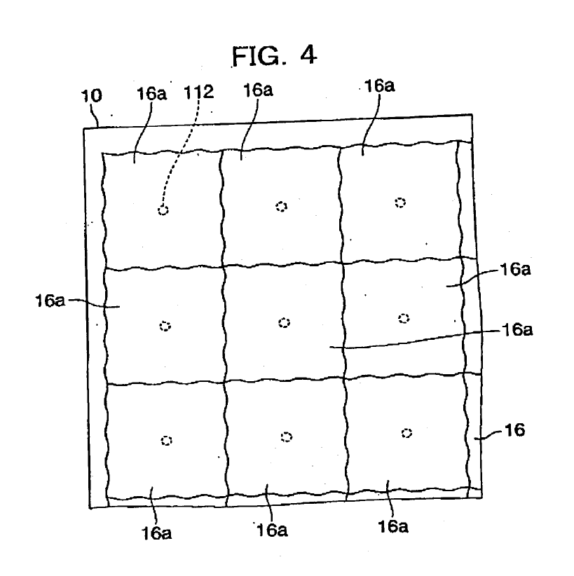

FIG. 4 is a plan view illustrating the silicon film 16 formed on the glass substrate 10. As shown in FIG. 4, each of the silicon films 16a is formed within a region which nearly coincides with an area in which one cell C is expected to be formed. By using the substantially monocrystalline silicon films 16 obtained by doing so as the active regions (source/drain regions, channel regions) of thin-film transistors, it is possible to form the thin-film transistors whose off current is small and whose electron mobility is high.

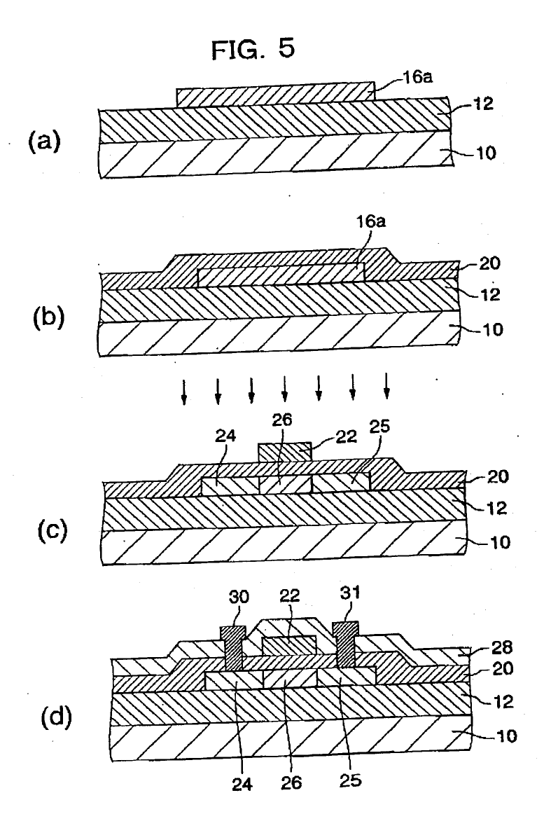

Next, a step of forming the thin-film transistor using the silicon film 16a is explained below. FIGS. 5(a)-5(d) are schematics illustrating forming the thin-film transistor T. FIGS. 5(a)-5(d) show in sectional view one thin-film transistor T, taken along plane B-B′ shown in FIG. 2(a).

As shown in FIG. 5(a), the silicon film 16a is shaped by patterning the silicon film 16a and removing the portions unnecessary for the formation of the thin-film transistor T. After patterning, the silicon film 16a is used for the formation of an active region of the thin-film transistor.

Next, as shown in FIG. 5(b), a silicon oxide film 20 is formed on the upper surface of the silicon oxide film 12 and the silicon film 16a by an electron cyclotron resonance PECVD method (ECR-PECVD), a PECVD method, or the like. The silicon oxide film 20 functions as a gate insulating film in the thin-film transistor.

Next, as shown in FIG. 5(c), after forming a thin-film of metals such as tantalum and aluminum by a film formation method, such as a sputtering method, followed by performing patterning thereof, a gate electrode 22 and a gate wiring film are formed. Then, by introducing impurity elements to be donors or acceptors using the gate electrode 22 as a mask, that is, by carrying out self-aligned ion implantation, the source region 24, the drain region 25, and the channel region 26 are formed in the silicon film 16a. For example, in the present exemplary embodiment, by introducing phosphorus (P) as an impurity element and then irradiating with XeCl excimer laser light with an energy density of about 400 mJ/cm² to activate the impurity element, an N-type thin-film transistor is formed. Further, instead of laser irradiation, the activation of the impurity element can also be carried out by carrying out heating at a temperature of about 250 to 400° C.

Next, as shown in FIG. 5(d), a silicon oxide film 28 having a thickness of about 500 nm is formed on the upper surface of the silicon oxide film 20 and the gate electrode 22 by a film formation method, such as a PECVD method. Then, by forming contact holes reaching each of the source region 24 and the drain region 25 through the silicon oxide films 20 and 28, placing metal, such as aluminum or tungsten, in the contact holes by a film formation method, such as a sputtering method, and then patterning the metal, a source electrode 30 and a drain electrode 31 are formed. The thin-film transistor T of the present exemplary embodiment is formed by the above manufacturing method.

Like the above, in the present exemplary embodiment, paying attention to the regularity in the array positions of the respective cells C on the substrate, since the plurality of grain filters 112 can be formed to have a pitch nearly equal to the array pitch P1 of the plurality of cells C (that is, a pitch one times the array pitch of the cells C) and the crystal grains are grown by carrying out crystallization of the semiconductor film, it is possible to form a plurality of crystal grains with an array pitch corresponding to the regularity in the array positions of the cells C. As a result, the thin-film circuit 1 can be formed such that one cell is included in one crystal grain formed substantially centered around the grain filter 112. Therefore, it is possible to eliminate the occurrence of grain boundaries in the respective cells C, thus improving the characteristics of the thin-film transistors T constituting the respective cells C. Furthermore, since the difference in characteristics between the respective thin-film transistors T caused by the presence or absence of the grain boundaries can be prevented or reduced, it is possible to reduce or suppress non-uniformity in characteristics between the respective thin-film transistors constituting the respective cells C.

Also, although the respective grain filters 112 are formed on the glass substrate 10 so as to have a pitch equal to the array pitch P1 of the cells C, that is, a pitch P obtained by multiplying the array pitch P1 by the natural number 1 (see FIG. 2) in the above first exemplary embodiment, the respective grain filters 112 may be formed to have a pitch obtained by multiplying the array pitch P1 by 2 or a larger natural number.

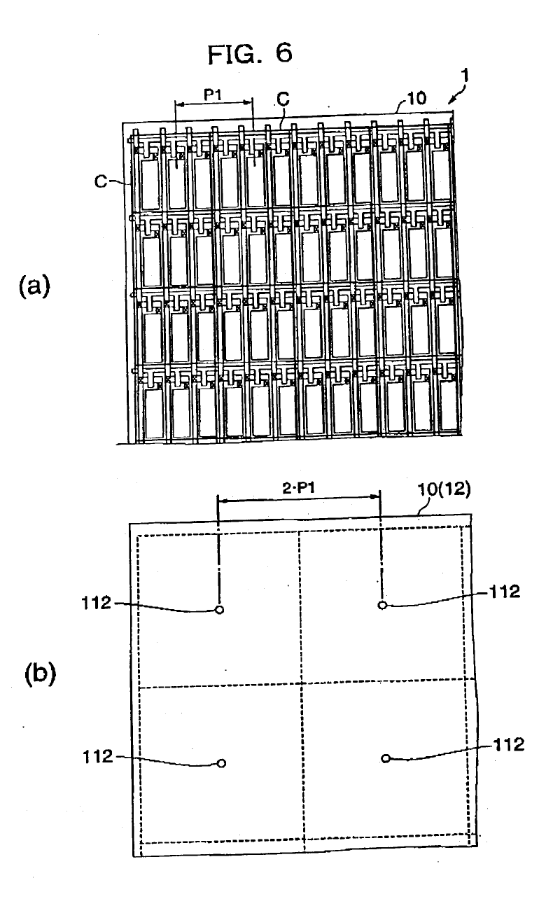

FIGS. 6(a) and 6(b) are schematics illustrating an exemplary embodiment in which the grain filters 112 are formed with a pitch two times the array pitch P1 of the cells C. The respective grain filters 112 are formed in the silicon oxide film 12 formed on the glass substrate 10 so as to have a pitch 2·P1 obtained by multiplying the array pitch P1 (FIG. 6(a)) of the cells C by the natural number 2 (FIG. 6(b)). Thereafter, as in the aforementioned exemplary embodiment, by carrying out the step of forming the silicon film (see FIG. 3) and the step of forming the thin-film transistors T using the formed silicon film (see FIG. 4), the thin-film circuit 1 is formed.

Like the above, when the grain filters 112 are formed with a pitch two times the array pitch P1 of the cells C, since the crystal grains can be grown with a pitch two times the array pitch P1 of the cells C, the thin-film circuit 1 can be formed such that one to four (four in the aforementioned example) cells C are included in one crystal grain formed substantially centered around the grain filter 112.

[Second Exemplary Embodiment]

In the first exemplary embodiment described above, the array positions of the grain filters 112 are determined on the basis of the pitch obtained in conjunction with the array pitch P1 of cells C. However, paying attention to the regularity in the array pitch of the respective thin-film transistors T included in the cells C, it is also possible to set the formation pitch of the grain filters 112 so as to have a proper value of n (n is a natural number) times the array pitch of the respective thin-film transistors T. Details thereof are explained below.

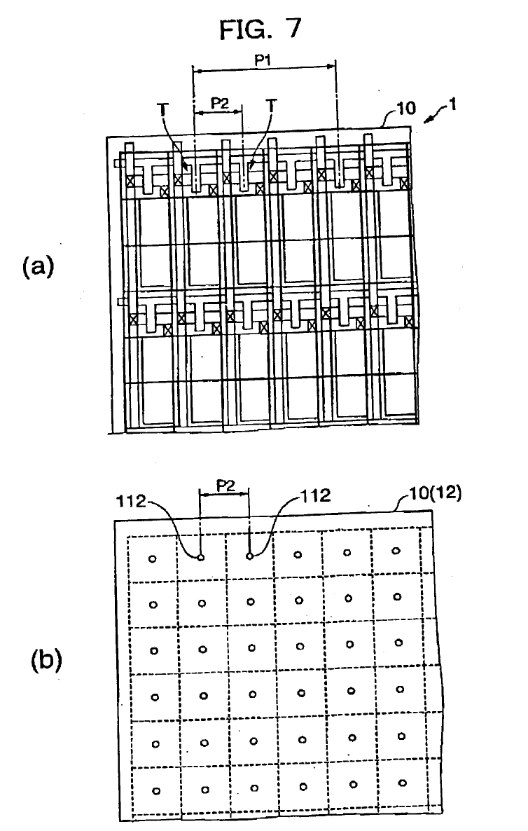

FIGS. 7(a) and 7(b) are schematics illustrating an exemplary embodiment in which the grain filters 112 are formed with a pitch one times the array pitch of the thin-film transistors T. The respective grain filters 112 are formed in the silicon oxide film 12 formed on the glass substrate 10 so as to have a pitch equal to the array pitch P2 (see FIG. 7(a)) of the thin-film transistors T, that is, a pitch P2 obtained by multiplying the array pitch P2 by the natural number 1 (FIG. 7(b)). Thereafter, as in the aforementioned exemplary embodiment, by carrying out the step of forming the silicon film (see FIG. 3) and the step of forming the thin-film transistors T using the formed silicon film (see FIG. 4), the thin-film circuit 1 is formed.

Furthermore, as in the example shown in FIGS. 7(a) and 7(b), since the array pitch of the plurality of cells C is P1, the number of the thin-film transistors T included in one cell C is 3 and since the array pitch in forming the grain filters 112 can be expressed as (⅓)×P1, the same results can be obtained by forming the grain filters 112 on the basis of such correspondence.

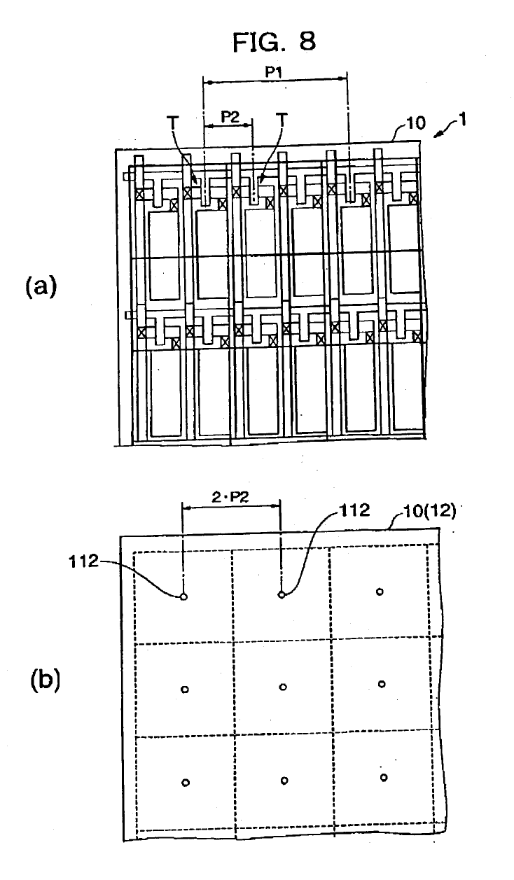

FIGS. 8(a) and 8(b) are schematics illustrating an example in which the grain filters 112 are formed with a pitch two times the array pitch P2 of the thin-film transistors T. The respective grain filters 112 are formed in the silicon oxide film 12 formed on the glass substrate 10 so as to have a pitch 2·P2 obtained by multiplying the array pitch P2 (see FIG. 8(a)) of the thin-film transistors T by the natural number 2 (FIG. 8(b)). Thereafter, as in the aforementioned exemplary embodiment, by carrying out the step of forming the silicon film (see FIG. 3) and the step of forming the thin-film transistors T using the formed silicon film (see FIG. 4), the thin-film circuit 1 is formed.

Furthermore, as in the example shown in FIGS. 8(a) and 8(b), since the array pitch of the plurality of cells C is P1, the number of thin-film transistors T included in one cell C is 3 and since the array pitch in forming the grain filters 112 can be expressed as (⅔)×P1, the grain filters 112 may be formed on the basis of such correspondence.

Like the above, paying attention to the regularity in the array positions of the respective thin-film transistors T included in the respective cells C, by forming the plurality of grain filters 112 so as to have a pitch n times the array pitch P2 of the plurality of thin-film transistors T and by growing the crystal grains by carrying out crystallization of the semiconductor film, it is possible to form a plurality of crystal grains with an array pitch corresponding to the regularity in the array positions of the thin-film transistors T. Specifically, when 1 is selected as n, it is possible to form the crystal grains with a pitch one times the array pitch P2 of the thin-film transistors T. By doing so, the thin-film circuit 1 can be formed such that one thin-film transistor T is included in one crystal grain. Further, when 2 is selected as n, it is possible to form the crystal grains with a pitch two times the array pitch P2 of the thin-film transistors T. By doing so, the thin-film circuit 1 can be obtained such that one to four (two in the above example) thin-film transistors T are included in one crystal grain.

That is, in the second exemplary embodiment, the thin-film circuit 1 can be formed such that one crystal grain includes at least one thin-film transistor T as a whole. Therefore, it is possible to reduce or eliminate the occurrences of grain boundaries in the respective thin-film transistors T, thus enhancing the characteristics of the thin-film transistors T constituting the respective cells C. Furthermore, since the difference in characteristics between the respective thin-film transistors T caused by the presence or absence of the grain boundaries can be reduced or prevented, it is possible to reduce or suppress the non-uniformity in characteristics between the respective thin-film transistors T constituting the respective cells C. Furthermore, although the detailed explanation is omitted, the grain filters 112 may be formed on the basis of a pitch obtained by multiplying the array pitch P2 of the thin-film transistors T by 3 or a larger natural number.

[Specific Examples of Electro-Optical Devices]

Specific examples of an electro-optical device according to the present invention are explained below. The semiconductor devices in the respective embodiments above can be used in constituting electro-optical devices, such as a liquid-crystal display device or an organic electroluminescent display device, for example. As described above, since the respective thin-film transistors T constituting the thin-film circuit 1 have excellent characteristics and small non-uniformity in characteristics, by using the thin-film circuit 1, it is possible to reduce or prevent irregular color, irregular luminescence, and the like, and to construct a display device having an excellent display quality. Although examples of electronic apparatuses including such a display device are explained below, application of the present invention is not limited to the examples.

<Mobile Computer>

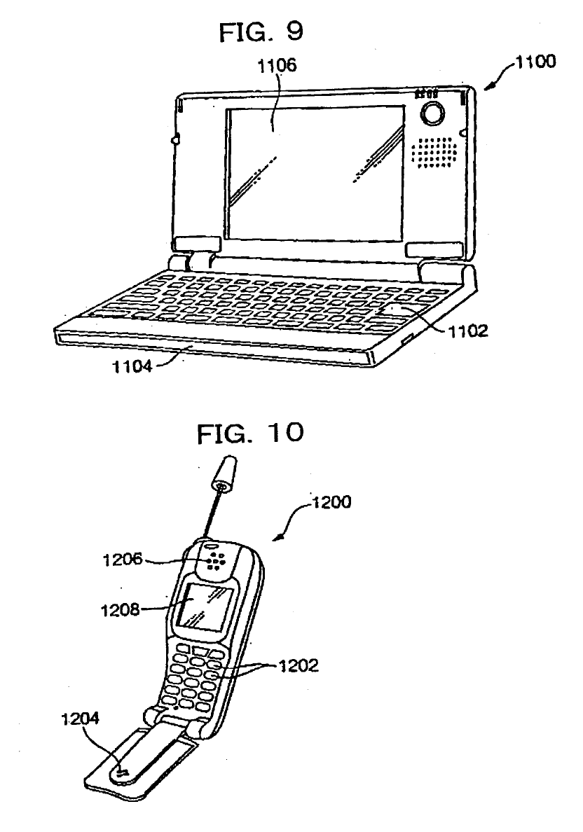

First, an example in which a display device including thin-film transistors according to the present invention is applied to a mobile personal computer (data processing unit) is explained below. FIG. 9 is a perspective view illustrating a personal computer. In FIG. 9, a personal computer 1100 includes a main body 1104 having a keyboard 1102 and a display unit having a display device 1106 as described above.

<Mobile Phone>

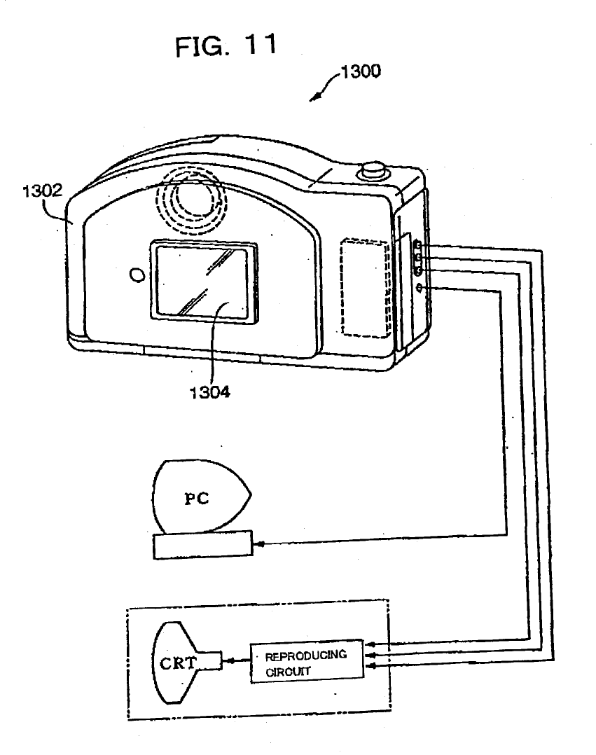

Next, an example in which a display portion according to the above exemplary embodiment is applied to the display unit of a mobile phone is explained below. FIG. 10 is a perspective view illustrating a mobile phone. In FIG. 10, a mobile phone 1200 includes a display device 1208 as described above together with a receiver 1204 and a transmitter 1206, in addition to a plurality of manipulating buttons 1202.

<Digital Still Camera>

A digital still camera using the display device according to the above exemplary embodiments as a finder is explained below. FIG. 11 is a perspective view illustrating a digital still camera. A conventional camera exposes a film to light with an optical image of a subject. In contrast, a digital still camera 1300 performs photoelectric conversion of an optical image of a subject by an image pickup device, such as a CCD (charge coupled device), to generate image pickup signals. The rear surface of a case 1302 of the digital still camera 1300 is provided with a display device 1304 as described above, and it is constructed to carry out display on the basis of image pickup signals from the CCD. For this reason, the display device 1304 functions as a finder to display a subject. Furthermore, the observing side (the back side in FIG. 11) of the case 1302 is provided with a light receiving unit having an optical lens, a CCD or the like.

<Electronic Book>

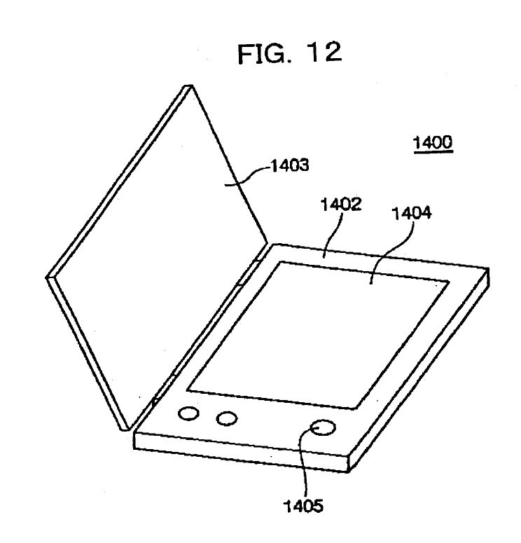

FIG. 12 is a perspective view illustrating an electronic book using a display device according to the present invention. In FIG. 12, reference numeral 1400 indicates an electronic book. The electronic book 1400 includes a book-shaped frame 1402 and a cover 1403 capable of being opened and closed with respect to the frame 1402. The frame 1402 is provided with a display device 1404, leaving a display face thereof exposed at the surface of the frame, and a manipulating unit 1405. A controller, a counter, a memory, and the like are provided in the inner portion of the frame 1402.

Further, as an electronic apparatus or a data processing unit, in addition to the personal computer, the mobile phone, the digital still camera, and the electronic book described above, electronic paper, a liquid-crystal TV, a video tape recorder of the viewfinder type or monitor-viewing type, a car navigation device, a pager, an electronic notebook, a calculator, a word processor, a work station, a TV phone, a POS terminal, and equipment including a touch panel, for example, can be used. The aforementioned display device can be used as the display unit(s) of such various and other electronic apparatuses.

Furthermore, in the above description, although the formation of the thin-film circuit used in the display devices has been explained in detail, the range of application of the present invention is not limited to such devices, and the present invention can be applied to various other semiconductor devices, such as a memory device (for example, ROM, RAM etc.) constructed by arranging a plurality of unit memory circuits, or a field-programmable gate array device constructed by arranging a plurality of unit logic circuits, for example.

[Advantages]

As described above, according to the present invention, since the thin-film circuit is formed so that one crystal grain includes at least one unit circuit as a whole, it is possible for the respective unit circuit not to include grain boundaries. Further, according to the present invention, since the thin-film circuit is formed so that one crystal grain includes at least one thin-film element as a whole, it is possible for the respective thin-film element not to include grain boundaries. Therefore, enhancements in the characteristics of the thin-film elements (for example, semiconductor element) constituting the respective unit circuits can be obtained. Furthermore, since the difference in characteristics between the respective thin-film elements caused by the presence or absence of the grain boundaries can be prevented, it is possible to reduce or suppress non-uniformity in the characteristics between the respective thin-film elements constituting the respective unit circuits.

What is claimed is:

1. A method of manufacturing a semiconductor device having a thin-film circuit constructed by arranging a plurality of unit circuits having thin-film elements on an insulating substrate, comprising:
forming a plurality of seed portions to be seeds in crystallizing a semiconductor film on said insulating substrate;
forming the semiconductor film on said insulating substrate on which said seed portions have been formed;
crystallizing said semiconductor film by carrying out heating; and
forming said thin-film circuit in said semiconductor film on which said heating has been carried out, said plurality of seed portions being formed to have a pitch n times an array pitch of said plurality of unit circuits.

2. A method of manufacturing a semiconductor device having a thin-film circuit constructed by arranging a plurality of unit circuits having thin-film elements on an insulating substrate, comprising:
forming a plurality of seed portions to be seeds in crystallizing a semiconductor film on said insulating substrate;
forming the semiconductor film on said insulating substrate on which said seed portions have been formed;
crystallizing said semiconductor film by carrying out heating; and
forming said thin-film circuit in said semiconductor film on which said heating has been carried out, said plurality of seed portions being formed to have a pitch n times an array pitch of the respective thin-film elements included in each of said unit circuits.

3. The method for manufacturing a semiconductor device as claimed in claim 1, further including providing seed portions that are concave portions formed in said insulating substrate.

4. The method for manufacturing a semiconductor device as claimed in claim 3, the crystallizing including performing heating on condition that said semiconductor film in said concave portions is not melted and other portions thereof are melted.

5. The method for manufacturing a semiconductor device as claimed in claim 1, the crystallizing including performing heating by laser irradiation.

6. The method for manufacturing a semiconductor device as claimed in claim 1, the forming the semiconductor film including forming semiconductor film that is at least one of an amorphous and a polycrystalline silicon film.

7. The method for manufacturing a semiconductor device as claimed in claim 1, said thin-film elements being thin-film transistors.

8. The method for manufacturing a semiconductor device as claimed in claim 7, said unit circuits being pixel circuits of an electro-optical device.

9. The method for manufacturing a semiconductor device as claimed in claim 7, said unit circuits being unit memory circuits of a memory device.

10. The method for manufacturing a semiconductor device as claimed in claim 7, said unit circuits being unit logic circuits of a field-programmable gate array device.

11. A semiconductor device, comprising:
a thin-film circuit, including:
an insulating substrate; and
a plurality of unit circuits having thin-film elements arranged on the insulating substrate;
said insulating substrate defining step portions formed to have a pitch n times an array pitch of said plurality of unit circuits; and
each of said plurality of unit circuits being formed by a substantially monocrystalline semiconductor film by carrying out heating on said semiconductor film formed on said insulating substrate to crystallize said semiconductor film using said step portions as seeds.

12. A semiconductor device, comprising:
a thin-film circuit, including:
an insulating substrate; and
a plurality of unit circuits having thin-film elements arranged on the insulating substrate;
said insulating substrate defining step portions formed to have a pitch n times an array pitch of the respective thin-film elements included in said unit circuits; and
said thin-film elements being formed by a substantially monocrystalline semiconductor film by carrying out heating on said semiconductor film formed on said insulating substrate to crystallize said semiconductor film using said step portions as seeds.

13. The semiconductor device as claimed in claim 11, said step portions being concave portions formed in an insulating film deposited on said insulating substrate.

14. The semiconductor device as claimed in claim 11, said semiconductor film formed on said insulating substrate being at least one of an amorphous and a polycrystalline silicon film.

15. The semiconductor device as claimed in claim 11, said thin-film element including a thin-film transistor.

16. The semiconductor device as claimed in claim 15, said unit circuit being a pixel circuit of an electro-optical device.

17. The semiconductor device as claimed in claim 15, said unit circuit being a unit memory circuit of a memory device.

18. The semiconductor device as claimed in claim 15, said unit circuit being a unit logic circuit of a field-programmable gate array device.

19. An electro-optical device, comprising:
the pixel circuit as claimed in claim 16.

20. An electronic apparatus, comprising:
the electro-optical device as claimed in claim 19.
